(19) United States
(12) Patent Application Publication
(10) Pub. No.: US 2006/0172452 A1
(43) Pub. Date: Aug. 3, 2006

(54) Detector

(75) Inventors: Volker Seyfried, Nussloch (DE); Frank Schreiber, Dossenheim (DE)

Correspondence Address: DAVIDSON, DAVIDSON & KAPPEL, LLC, 485 SEVENTH AVENUE, 14TH FLOOR, NEW YORK, NY, 10018, US

(73) Assignee: Leica Microsystems CMS GmbH, Wetzlar (DE)

(21) Appl. No.: 11/343,022

(22) Filed: Jan. 30, 2006

Related U.S. Application Data
(60) Provisional application No. 60/650,277, filed on Feb. 4, 2005.

(30) Foreign Application Priority Data
Jan. 31, 2005 (DE) 10 2005 004 545.6

(51) Int. Cl. H01L 21/00; H01L 21/82; G02B 21/00

(52) U.S. Cl. 438/70; 438/128; 359/368

(57) ABSTRACT

A detector includes a CCD arrangement having at least one CCD, and a focusing device. The focusing device focuses spectrally separated light onto the CCD arrangement. The focusing device is located in an optical path before the CCD arrangement, and includes a microlens arrangement having at least one microlens.

Priority is claimed to provisional application No. 60/650,277, filed Feb. 4, 2005, and to German patent application DE 10 2005 004 545.6, filed on Jan. 31, 2005, the entire subject matters of both of which are hereby incorporated by reference herein.

The present invention relates to a detector, especially for spectral detection of light in a microscope, including a CCD arrangement having at least one CCD; a means for focusing a spectrally separated light onto the CCD arrangement being disposed in an optical path before the CCD arrangement.

### BACKGROUND

Detectors of the type mentioned at the outset are known in the field, and are used, for example, in a confocal microscope for spectral detection. In this instance, the light is collimated by a lens after the detection pinhole of the confocal microscope, the collimated light is spectrally separated in a dispersive element, such as a grating, a prism, or a hologram, and the spectrally separated light is focused by a lens onto the CCD arrangement.

However, the known systems are problematic in that the achievable spot diameters are typically on the order of from 100 μm to 600 μm—depending on the size of the confocal pinhole—both the direction of the spectral separation and in the direction perpendicular thereto. This exceeds the size of individual pixels in common CCDs many times. This disadvantage may in principle be overcome either by using larger pixels or by using a plurality of pixels for reading out a single spot. In both cases, however, the read-out time required per spot, i.e., per detection wavelength is increased significantly, so that the detection speed is too low for most tasks.

### SUMMARY OF THE INVENTION

It is therefore an object of the present invention to provide a detector and a spectrometer, as well as a microscope, including a CCD arrangement having at least one CCD and a means for focusing a spectrally separated light onto the CCD arrangement disposed in disposed in an optical path before the CCD arrangement, whereby a high detection speed is achieved with structurally simple means.

The present invention provides a detector comprising a CCD arrangement having at least one CCD. A means for focusing a spectrally separated light onto the CCD arrangement is disposed in an optical path before the CCD arrangement. The focusing means includes a microlens arrangement having at least one microlens. The detector is especially suitable for spectral detection of light in a microscope.

In accordance with the present invention, it was discovered, for of all, that it is perfectly possible to achieve high detection speeds also in spectral detection with CCD detectors. Further, according to the present invention, a microlens arrangement having at least one microlens is provided here as a means for focusing a spectrally separated light onto the CCD arrangement. By using microlenses, it is possible to focus a single detection wavelength or a single detection wavelength range onto a single CCD pixel. Therefore, only a single pixel needs to be read out to detect a single detection wavelength or a single detection wavelength range.

Consequently, the detector provided by the present invention is a detector with which a particularly high detection speed is achieved with structurally simple means.

To ensure a particularly high detection speed and a particularly reliable detection of spectrally separated light, the microlens arrangement for focusing could be formed in the direction of the spectral separation and preferably additionally in a direction perpendicular thereto. In this manner, the detector covers a particularly large space or surface area.

Specifically, the microlens arrangement could be a two-dimensional microlens array. This ensures reliable coverage of the desired space or surface area.

Possible microlenses include, for example, gradient-index lenses (GRIN). Therefore, the microlenses could include at least one gradient-index lens.

Preferred lenses are spherical lenses. Therefore, the microlenses could include at least one spherical lens. In a particularly preferred embodiment, the microlenses could be exclusively spherical lenses. In this instance, the microlens or microlenses could have a spherical opening.

Also, with a view to a particularly high detection speed and a particularly reliable detection of spectrally separated light, the microlenses could include a combination of an array of cylindrical microlenses preferably focusing in the direction of the spectral separation, and at least one cylindrical lens focusing in the direction perpendicular thereto. The at least one cylindrical lens could in principle be a single cylindrical lens, a cylindrical microlens, a rod lens, or an array of such lenses. The at least one cylindrical lens should be selected according to the particular application.

As a general rule, care should be taken that the focus is located on the CCD arrangement in both spatial directions, respectively. The microlenses for focusing in the two directions could have different focal lengths, specifically for this purpose. In particular in this case, the microlenses for the two directions could be disposed on the same substrate in a structurally particularly simple manner. Thus, a particularly easy-to-operate microlens arrangement is achieved. In this instance, the microlenses for the two directions could be disposed on different sides of the substrate.

In order to adapt the CCD arrangement to an asymmetric optical resolution, the microlens arrangement could include asymmetric lenses, in which case, as also in general, the microlens arrangement could be made up of an array, a line, or a single lens.

The microlens arrangement could include a combination of two crossed arrays of lenses or cylindrical lenses, preferably comprised of asymmetric lenses.

In order to achieve a particularly easy-to-operate microlens arrangement, the arrays of lenses or cylindrical lenses for the two directions could be disposed on the same substrate. Furthermore, the arrays of lenses or cylindrical lenses for the two directions could advantageously be disposed on different sides, for example, on the front and on the back, of the substrate.

In an embodiment that is structurally advantageous, the microlens arrangement could be used as a window for preferably hermetic sealing, in particular vacuum-sealing, of deeply cooled CCDs.

The lens size of the individual microlenses of the microlens arrangement in the direction of the spectral detection could advantageously be adapted to the specific spectral resolution at the particular wavelength. In this manner, it is possible to compensate for the nonlinear separation of the spectrum, which occurs, for example, when prisms are used as the dispersive elements.

Chromatic errors could advantageously be compensated for by individually adapting the individual microlenses.

It is an advantage of the detector of the present invention that by using microlenses, a space is created between the light-sensitive pixels of the CCD arrangement; this space being usable for additional features and/or components. The space created by the microlenses between the light-sensitive pixels of the CCD arrangement could be used, for example, to place at least one shift register. Moreover, the space could alternatively or additionally be used to place at least one anti-blooming barrier, which prevents crosstalk between pixels when there is too much light.

Alternatively or additionally, the space created by the microlenses between the light-sensitive pixels of the CCD arrangement could also be used for adding different pixels within the detection area. Another possible use of the space is the absorption of stray light. To this end, suitable absorption means could be placed in the space.

To increase transmission, the microlens arrangement could be coated. Alternatively or additionally, the microlens arrangement could be, preferably locally, provided with a surface coating to increase the absorption of or reduce stray light.

In order to achieve a particularly easy-to-operate detector, the microlens arrangement could be applied to, vapor-deposited on, or embossed onto the CCD arrangement. In this manner, a single component combining the functionality of the microlens arrangement and of the CCD arrangement is achieved.

The CCD arrangement could in principle be comprised of a single light-sensitive CCD pixel including a microlens. In one preferred specific embodiment, the CCD arrangement could include a CCD line array or a two-dimensional CCD array. In this connection, consideration should be given to the particular application and the desired ease of data processing.

In an advantageous embodiment, the CCD arrangement could include parallelized CCDs or preferably front-illuminated EMCCDs. In principle, it would be possible to use both back-illuminated EMCCDs and front-illuminated EMCCDs. The basic advantage of back-illuminated EMCCDs is the higher quantum efficiency, because the light does not have to pass through the gate structures of the EMCCD chip before it strikes the photoactive surface, which is usually associated with detection losses. The disadvantage of back-illuminated EMCCDs is that they are very thin and therefore difficult to manufacture and operate. By using the microlens arrangement of the present invention, space is made available on the front side of the EMCCD chip; no photoactive surface being needed in this space because the microlens arrangement focuses the light only onto selected chip regions. This space may be used for gate structures, thus eliminating the need to place gates above the photoactive surface. Thus, the front-illuminated EMCCDs, which are easier to manufacture and operate, can be used while, at the same time, providing high quantum efficiency. Here, the quantum efficiency is in the range of the common back-illuminated EMCCDs.

The present invention also provides a spectrometer having a detector, the detector comprising a CCD arrangement having at least one CCD. A means for focusing a spectrally separated light onto the CCD arrangement is disposed in an optical path before the CCD arrangement. The focusing means includes a microlens arrangement having at least one microlens.

Moreover, the present invention also provides a microscope, in particular a confocal or semi-confocal microscope, having a detector, the detector comprising a CCD arrangement having at least one CCD. A means for focusing a spectrally separated light onto the CCD arrangement is disposed in an optical path before the CCD arrangement. The focusing means includes a microlens arrangement having at least one microlens. In this instance, the microscope could have a single detection pinhole or a multi-spot or line scanner. In other words, the detector could be used both in confocal microscopes having a single detection pinhole or in confocal or semi-confocal microscopes having multi-spot or line scanners. In a multi-spot scanner, the number of cylindrical lenses or microlenses arranged in a direction perpendicular to the spectral separation could generally correspond to the number of spots.

In a line scanner, the cylindrical lenses or microlenses arranged in a direction perpendicular to the spectral separation could generally be omitted. Then, the number of CCD pixels in a direction perpendicular to the spectral separation corresponds to the number of pixels per scan line.

The detector of the present invention provides, as it were, a microlens CCD and preferably a microlens EMCCD, which can be used in conjunction with a spectrometer and a microscope, in particular a confocal microscope, or in conjunction with a line or multi-spot scanner.

With regard to the discussion of the advantages of particular embodiments of the inventive detector in connection with the claimed spectrometer or the claimed microscope, reference is made to the above description of these advantages in order to avoid repetitions.

### BRIEF DESCRIPTION OF THE DRAWINGS

The teaching of the present invention can be embodied and refined in different ways. The present invention is elaborated upon below based on exemplary embodiments with reference to the drawings. In the drawings,

FIG. 1 is a schematic view of an exemplary embodiment of an inventive detector in an optical path with spectral detection;

FIG. 2 is a schematic view of a further exemplary embodiment of an inventive detector in an optical path with spectral detection;

FIG. 3 is a schematic view of an exemplary embodiment of a microlens arrangement, in which cylindrical lenses are disposed on both sides of a substrate;

FIG. 4 is a schematic view of a further exemplary embodiment of a microlens arrangement, in which cylindrical lenses are disposed on both sides of a substrate, and the microlens size increases along the direction of the spectral separation;

FIG. 5 is a schematic view of a further exemplary embodiment of a microlens arrangement, in which cylindrical lenses are disposed on both sides of a substrate; and

FIG. 6 is a schematic example of the use of freed spaces for electronic charge summation on a CCD arrangement.

### DETAILED DESCRIPTION

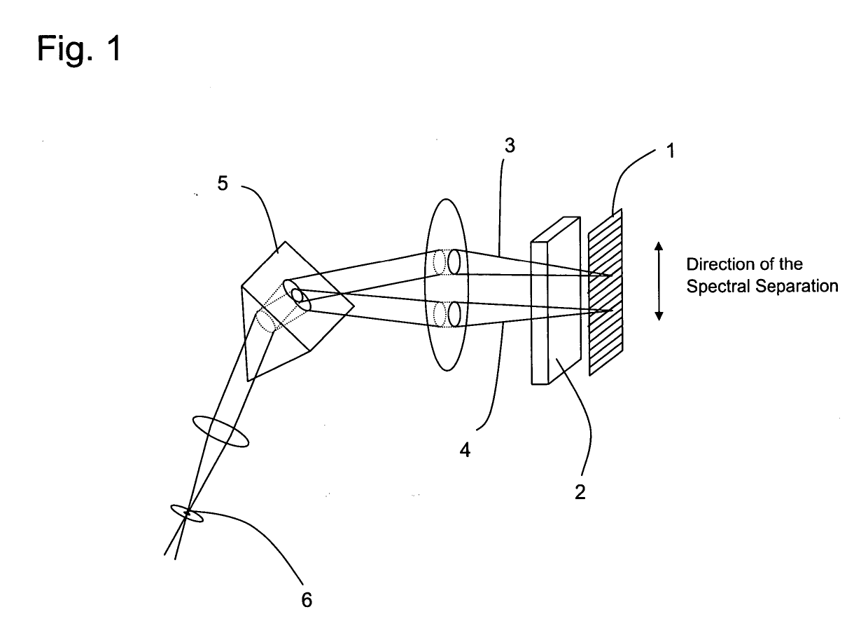

FIG. 1 is a schematic view of an exemplary embodiment of an inventive detector, especially for spectral detection of light in a microscope. The detector has a CCD arrangement 1 having at least one CCD; a means for focusing a spectrally separated light onto CCD arrangement 1 being disposed in an optical path before CCD arrangement 1. With a view to a particularly high detection speed, the means includes a microlens arrangement 2 having at least one microlens.

In the exemplary embodiment shown in FIG. 1, two light beams 3 and 4, which have been spectrally split by a prism 5, are focused onto CCD arrangement 1. A detection pinhole 6 is disposed in the optical path before prism 5.

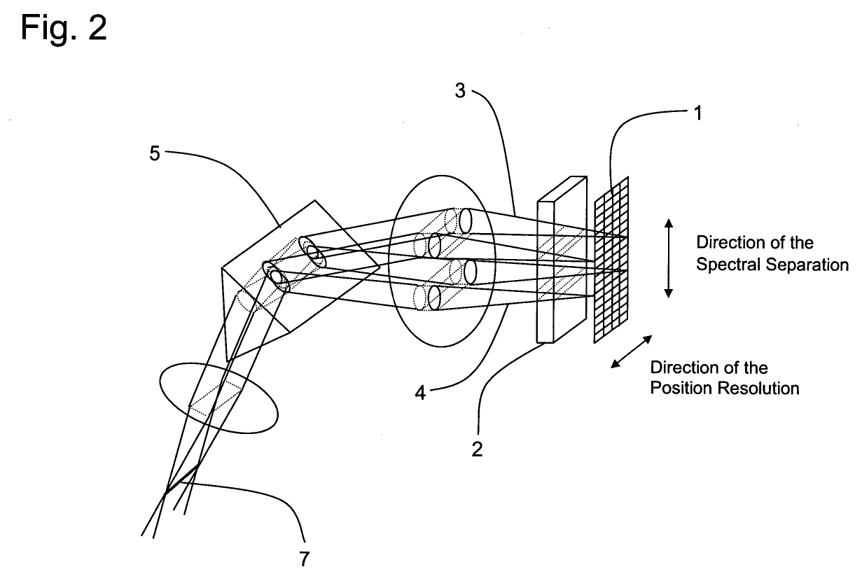

FIG. 2 is a schematic view of a further exemplary embodiment of an inventive detector; a line scanner being used here. Moreover, in the optical path before prism 5 producing light beams 3 and 4, there is disposed a detection slit diaphragm 7.

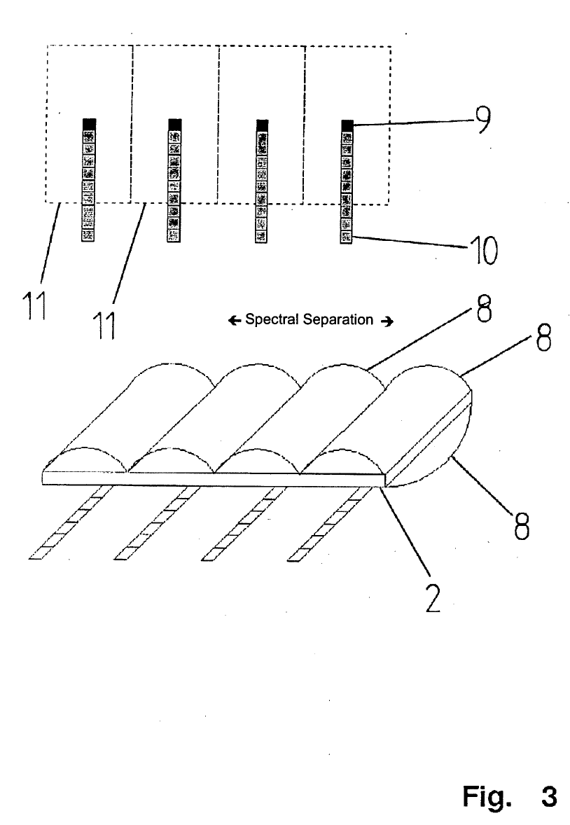

FIGS. 3, 4 and 5 each show microlens arrangements 2 having individual microlenses 8. Microlenses 8 are disposed on the same substrate on the front and back sides thereof. The exemplary embodiments shown in FIGS. 3 through 5 differ in the arrangement of microlenses 8. Each microlens 8 is assigned a CCD pixel 9 having a shift register 10. In this connection, the detection area 11 associated with a particular microlens 8 is shown in dashed lines.

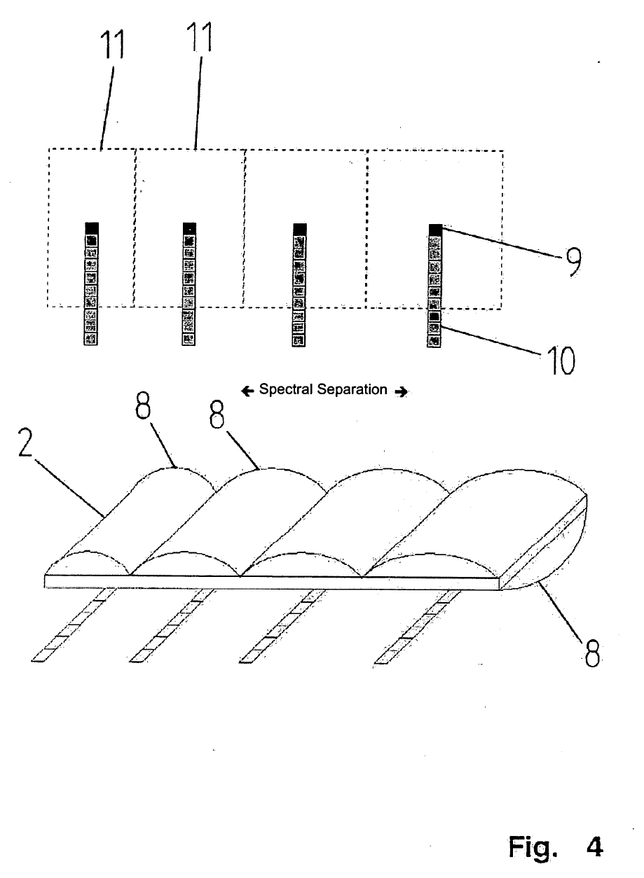

In the exemplary embodiment shown in FIG. 3, microlenses 8 of identical size are arranged equidistantly along the direction of the spectral separation. In the exemplary embodiment shown in FIG. 4, the size of microlenses 8 increases along the direction of the spectral separation for optimum adaptation in the case of nonlinear dispersion, for example, when using a prism 5. The spacing of CCD pixels 9 also increases correspondingly.

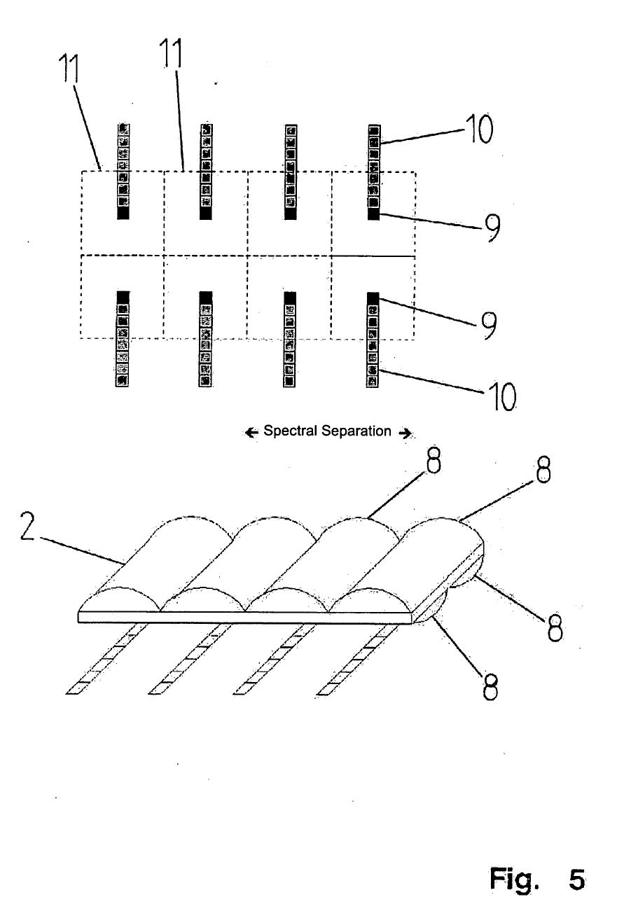

In the exemplary embodiment shown in FIG. 5, a plurality of CCD pixels 9 are arranged in a direction perpendicular to the direction of the spectral separation, which results in a correspondingly adapted microlens arrangement 2 with microlenses 8 on the top and bottom sides of the substrate.

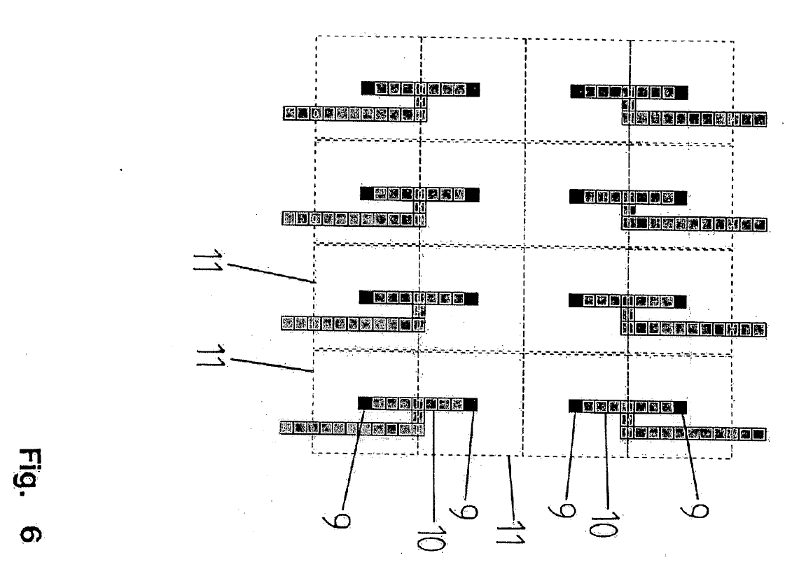

FIG. 6 shows how the spaces freed by the inventive detector are used for electronic charge summation. Here, one CCD shift register 10 is assigned to each two CCD pixels 9. However, CCD pixels 9 are each assigned to one detection area 11.

With regard to further advantageous embodiments of the inventive detector, reference is made to the general portion of the specification and to the appended patent claims in order to avoid repetitions.

Finally, it should be particularly noted that the exemplary embodiments described above serve merely for discussion of the claimed teaching without limiting it to the exemplary embodiments.

What is claimed is:

1. A detector comprising:
a CCD arrangement including at least one CCD; and
a focusing device configured to focus spectrally separated light onto the CCD arrangement, the focusing device being disposed in an optical path before the CCD arrangement, the focusing device including a microlens arrangement including at least one microlens.

2. The detector as recited in claim 1 wherein the detector is configured for spectral detection of light in a microscope.

3. The detector as recited in claim 1 wherein the microlens arrangement is arranged in a direction of spectral separation of the light.

4. The detector as recited in claim 3 wherein the microlens arrangement is arranged in a direction perpendicular to the direction of the spectral separation.

5. The detector as recited in claim 1 wherein the microlens arrangement includes a two-dimensional microlens array.

6. The detector as recited in claim 1 wherein the at least one microlens includes at least one gradient-index lens.

7. The detector as recited in claim 1 wherein the at least one microlens includes at least one spherical lens.

8. The detector as recited in claim 1 wherein each of the at least one microlens is a spherical lens.

9. The detector as recited in claim 1 wherein the at least one microlens includes a spherical opening.

10. The detector as recited in claim 1 wherein the at least one microlens includes an array of cylindrical microlenses and at least one cylindrical lens configured to focus in a direction perpendicular to a direction of spectral separation of the light.

11. The detector as recited in claim 10 wherein the array of cylindrical microlenses is configured to focus in the direction of the spectral separation.

12. The detector as recited in claim 10 wherein the at least one cylindrical lens includes at least one of a single cylindrical lens, a second cylindrical microlens, a rod lens, and an array thereof.

13. The detector as recited in claim 4 wherein first microlenses of the at least one microlens are arranged in the direction of the spectral separation and second microlenses of the at least one microlens are arranged perpendicular to the direction of the spectral separation, the first microlenses having a focal length different than a focal length of the second microlenses.

14. The detector as recited in claim 1 wherein the microlens arrangement includes asymmetric lenses.

15. The detector as recited in claim 1 wherein the microlens arrangement includes a combination of two crossed arrays of at least one of non-cylindrical and cylindrical lenses.

16. The detector as recited in claim 1 wherein first microlenses of the at least one microlens are arranged in the direction of the spectral separation and second microlenses of the at least one microlens are arranged perpendicular to the direction of the spectral separation, the first and second microlenses being disposed on a same substrate.

17. The detector as recited in claim 16 wherein the first and second microlenses are disposed on different sides of the substrate.

18. The detector as recited in claim 1 wherein the at least one CCD includes a deeply cooled CCD, and wherein the microlens arrangement is configured as a window for sealing the deeply cooled CCD.

19. The detector as recited in claim 18 wherein the sealing is a hermetic or vacuum sealing.

20. The detector as recited in claim 1 wherein a lens size of each microlens of the at least one microlens of the microlens arrangement is adapted, in a direction of a spectral detection, to a respective spectral resolution at a respective wavelength.

21. The detector as recited in claim 1 wherein the at least one microlens is adapted to compensate for a chromatic error.

22. The detector as recited in claim 1 further comprising a shift register associated with a space created by the at least one microlens between light-sensitive pixels of the CCD arrangement.

23. The detector as recited in claim 1 further comprising at least one anti-blooming barrier disposed in a space created by the at least one microlens between light-sensitive pixels of the CCD arrangement.

24. The detector as recited in claim 1 wherein a space created by the at least one microlens between light-sensitive pixels of the CCD arrangement is configured for adding different pixels within a detection area.

25. The detector as recited in claim 1 wherein a space created by the at least one microlens between light-sensitive pixels of the CCD arrangement is configured for absorbing stray light.

26. The detector as recited in claim 1 wherein the microlens arrangement is coated so as to increase transmission.

27. The detector as recited in claim 1 wherein the microlens arrangement has a surface coating so as to at least one of increase an absorption of and reduce stray light.

28. The detector as recited in claim 27 wherein the surface coating is a local surface coating.

29. The detector as recited in claim 1 wherein the microlens arrangement is at least one of applied to, vapor-deposited on, and embossed on the CCD arrangement.

30. The detector as recited in claim 1 wherein the CCD arrangement includes at least one of a CCD line array and a two-dimensional CCD array.

31. The detector as recited in claim 1 wherein the at least one CCD includes a plurality of parallelized CCDs.

32. The detector as recited in claim 1 wherein the at least one CCD includes a front-illuminated EMCCD.

33. A spectrometer comprising a detector as recited in claim 1.

34. A microscope comprising a detector as recited in claim 1.

35. The microscope as recited in claim 34 wherein the microscope is a confocal or semi-confocal microscope.

36. The microscope as recited in claim 35 comprising at least one of a single detection pinhole and a multi-spot or line scanner.
